(19) United States
(12) Patent Application Publication
(10) Pub. No.: US 2026/0362675 A1
(43) Pub. Date: Nov. 12, 2026

(54) SEMICONDUCTOR DEVICE HAVING AIR GAP

(71) Applicant: SAMSUNG ELECTRONICS CO., LTD., Suwon-si (KR)

(72) Inventors: Hyunjin LEE, Suwon-si (KR); Minsoo Kim, Suwon-si (KR); Yongkwan Kim, Suwon-si (KR); Huijung Kim, Suwon-si (KR)

(73) Assignee: SAMSUNG ELECTRONICS CO., LTD., Suwon-si (KR)

(21) Appl. No.: 19/639,869

(22) Filed: Apr. 6, 2026

(30) Foreign Application Priority Data
May 9, 2025 (KR) 10-2025-0060246

(51) Int. Cl. H10B 12/00; H10W 10/20

(52) U.S. Cl. CPC H10B 12/315; H10W 10/20

(57) ABSTRACT

A semiconductor device includes an active pattern including a first side surface and a second side surface opposite to the first side surface, the active pattern extending in a vertical direction, a bit line structure in contact with a lower surface of the active pattern, a contact structure in contact with an upper surface of the active pattern, and a word line structure in contact with the second side surface of the active pattern, the word line structure extending in a first horizontal direction. The word line structure includes vertical structures, a support layer, and an air gap. The vertical structures are spaced apart in a second horizontal direction that intersects the first horizontal direction and include word lines. The support layer is in contact with lower surfaces of the vertical structures. The air gap is between the vertical structures. The contact structure is exposed by the air gap.

### CROSS-REFERENCE TO RELATED APPLICATION

This application claims priority from Korean Patent Application No. 10-2025-0060246 filed on May 9, 2025 in the Korean Intellectual Property Office, the disclosure of which being incorporated by reference herein in its entirety.

### Background

The present disclosure relates to a semiconductor device having an air gap.

As demand for the implementation of high performance, high speed, and/or multifunctional operation of semiconductor devices increases, a degree of integration of semiconductor devices has been increasing. In manufacturing semiconductor devices having a fine pattern corresponding to the trend for a high degree of integration of semiconductor devices, it is advantageous to implement patterns having a fine width or a fine separation distance.

### SUMMARY

It is an aspect to provide a semiconductor device including a word line structure having an air gap disposed between word lines.

According to an aspect of one or more example embodiments, there is provided a semiconductor device including an active pattern including a first side surface and a second side surface opposite to the first side surface, the active pattern extending in a vertical direction, a bit line structure in contact with a lower surface of the active pattern, a contact structure in contact with an upper surface of the active pattern, and a word line structure in contact with the second side surface of the active pattern, the word line structure extending in a first horizontal direction. The word line structure may include vertical structures spaced apart from each other in a second horizontal direction that intersect the first horizontal direction, the vertical structure including word lines, a support layer in contact with lower surfaces of the vertical structures, and an air gap between the vertical structures. The contact structure may be exposed by the air gap.

According to another aspect of one or more example embodiments, there is provided a semiconductor device including an active pattern including a first side surface and a second side surface opposite to the first side surface, the active pattern extending in a vertical direction, a bit line structure in contact with a lower surface of the active pattern, a contact structure in contact with an upper surface of the active pattern, a back gate structure in contact with the first side surface of the active pattern, the back gate structure extending in a first horizontal direction and including a back gate electrode, and a word line structure in contact with the second side surface of the active pattern, the word line structure extending in the first horizontal direction. The word line structure may include vertical structures spaced apart from each other in a second horizontal direction that intersects the first horizontal direction, the vertical structures including word lines, a support layer in contact with lower surfaces of the vertical structures, capping patterns disposed at a level, the same as that of the support layer, and an air gap between the vertical structures. The support layer may include openings spaced apart from each other in the first horizontal direction. At least a portion of each of the capping patterns may be disposed in the openings.

According to yet another aspect of one or more example embodiments, there is provided a semiconductor device comprising an active pattern including a first side surface and a second side surface opposite to the first side surface, the active pattern extending in a vertical direction; a bit line structure and contact patterns in contact with the active pattern, the bit line structure and the contact patterns spaced apart from each other in the vertical direction with the active pattern interposed therebetween; an information storage structure connected to the contact patterns; a back gate structure in contact with the first side surface of the active pattern, the back gate structure extending in a first horizontal direction and including a back gate electrode; and a word line structure in contact with the second side surface of the active pattern, the word line structure extending in the first horizontal direction. The word line structure includes vertical structures spaced apart from each other in a second horizontal direction that intersects the first horizontal direction, the vertical structures including word lines; gate dielectric layers in contact with the second side surface of the active pattern and the vertical structures; a support layer overlapping the vertical structures in the vertical direction; and an air gap between the vertical structures. The gap exposes one of the bit line structure and the contact patterns, and a length of each of the vertical structures in the vertical direction is less than a length of each of the gate dielectric layers in the vertical direction.

### BRIEF DESCRIPTION OF DRAWINGS

The above and other aspects will be more clearly understood from the following detailed description, taken in conjunction with the accompanying drawings, in which:

FIG. 1 is a plan view of a semiconductor device according to an example embodiment;

FIG. 2 is longitudinal cross-sectional views of the semiconductor device illustrated in FIG. 1, taken along line I-I’ and line II-II’;

FIG. 3 is a partially enlarged view of the semiconductor device illustrated in FIG. 2;

FIG. 4 is a traverse cross-sectional view of the semiconductor device illustrated in FIG. 2, taken along line IV-IV’;

FIGS. 5-9 are longitudinal cross-sectional views of semiconductor devices according to example embodiments;

FIG. 10 is a longitudinal cross-sectional view of a semiconductor device according to an example embodiment;

FIG. 11 is a flowchart of a method of manufacturing a semiconductor device according to an example embodiment; and

FIGS. 12A, 12B, 13A, 13B, 14A, 14B, 15A, 15B, 16A, 16B, 17, 18, 19, 20A, 20B, 21A, 21B, 22, 23A, and 23B, are plan views and longitudinal cross-sectional views of sequential processes in a method of manufacturing a semiconductor device according to an example embodiment.

### DETAILED DESCRIPTION

Hereinafter, various example embodiments will be described with reference to the accompanying drawings as follows. As used in this specification, a phrase using the form “at least one of A, B, or C” includes within its scope “only A”, “only B”, “only C”, “A and B”, “A and C”, “B and C” and “A, B, and C.”

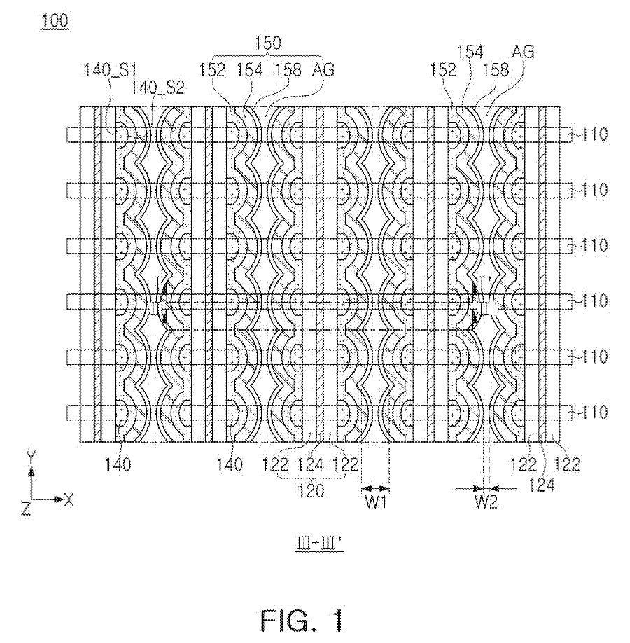

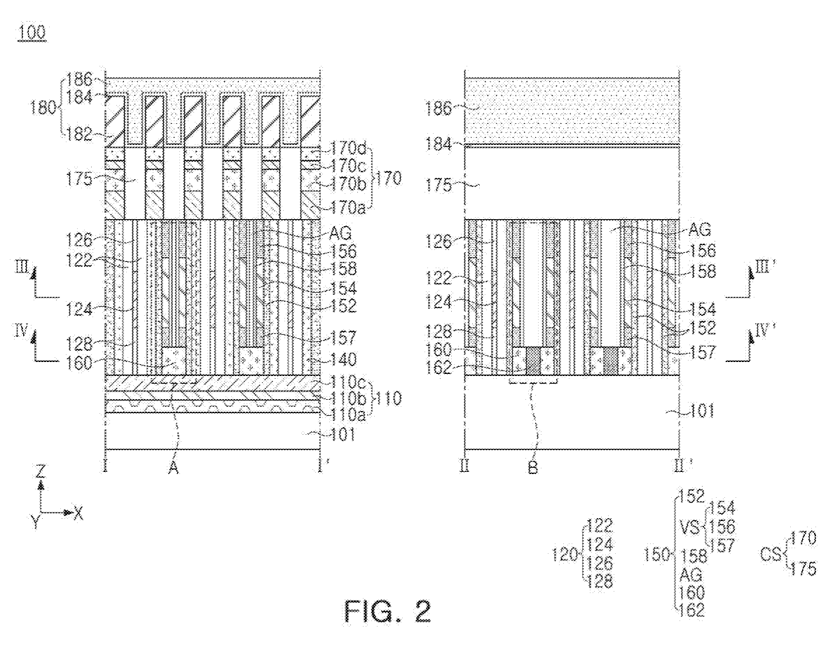

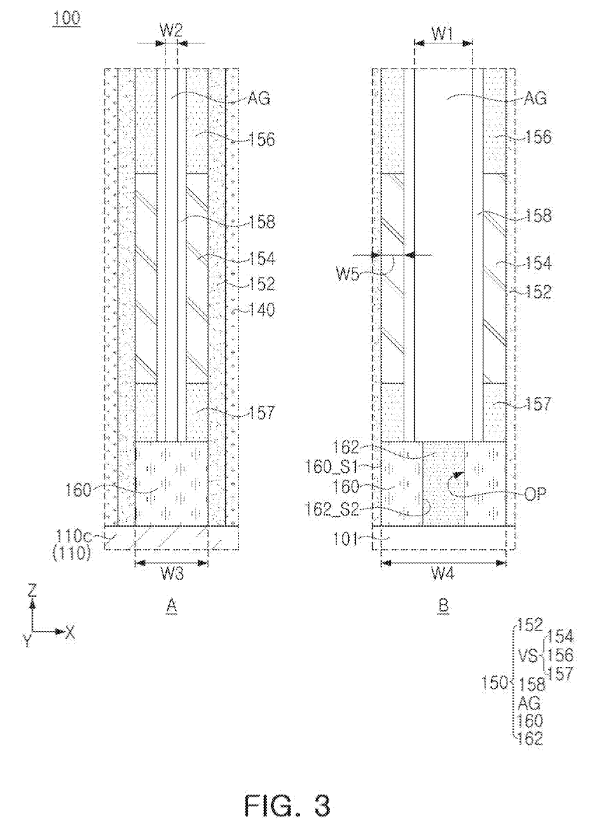

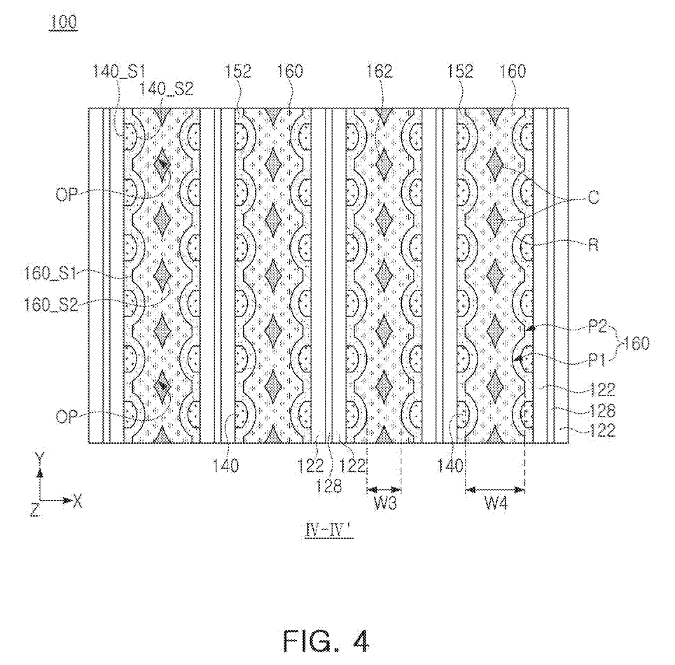

FIG. 1 is a plan view of a semiconductor device according to an example embodiment. FIG. 2 is a cross-sectional view of the semiconductor device illustrated in FIG. 1, taken along line I-I’ and line II-II’. FIG. 1 may correspond to a transverse cross-sectional view of the semiconductor device illustrated in FIG. 2, taken along line III-III’. FIG. 3 is a partially enlarged view of the semiconductor device illustrated in FIG. 2. FIG. 3 may correspond to region “A” and region “B” of FIG. 2. FIG. 4 is a transverse cross-sectional view of the semiconductor device illustrated in FIG. 2, taken along line IV-IV’.

Referring to FIGS. 1A-4, a semiconductor device 100 according to an example embodiment may include a lower insulating layer 101, a bit line structure 110, a back gate structure 120, an active pattern 140, a word line structure 150, a contact structure CS, and an information storage structure 180.

The semiconductor device 100 may include a vertical channel transistor including an active pattern 140, a bit line structure 110 electrically connected to the active pattern 140, and word lines 154 disposed on at least one side surface of the active pattern 140. The semiconductor device 100 may be applied to, for example, a cell array of a dynamic random access memory (DRAM), but example embodiments are not limited thereto.

The lower insulating layer 101 may include an insulating material such as silicon oxide, silicon nitride, silicon oxynitride (SiON), and/or silicon carbon nitride (SiCN).

The bit line structure 110 may extend on the lower insulating layer 101 in an X-direction. In an example embodiment, the bit line structure 110 may be buried in the lower insulating layer 101. The bit line structure 110 may be electrically connected to the active pattern 140. The bit line structure may be provided as a plurality of bit line structures 110, and the plurality of bit line structures 110 may be spaced apart from each other in a Y-direction, and may extend to be parallel to each other.

The bit line structure 110 may include doped polysilicon, a metal, a conductive metal nitride, a metal-semiconductor compound, a conductive metal oxide, graphene, carbon nanotubes, or combinations thereof. For example, at least one of the bit line structures 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof. In an example embodiment, the bit line structure 110 may include a first conductive pattern 110a, a second conductive pattern 110b, and a third conductive pattern 110c, sequentially stacked on the lower insulating layer 101. The first conductive pattern 110a may include, for example, a metal material such as titanium (Ti), tantalum (Ta), tungsten (W), and/or aluminum (Al), the second conductive pattern 110b may include, for example, a metal nitride such as titanium nitride (TiN) and/or a silicide material such as titanium silicide (TiSi), and the third conductive pattern 110c may include a semiconductor material such as polycrystalline silicon. The third conductive pattern 110c may be a layer doped with impurities. However, in some example embodiments, a material of layers of the bit line structure 110, the number of the layers, and a thickness of each of the layers included in the bit line structure 110 may be changed in various manners.

In an example embodiment, the semiconductor device 100 may further include shielding patterns disposed in the lower insulating layer 101. The shielding patterns may extend in the X-direction, and the shielding patterns may be spaced apart from each other in the Y-direction. For example, the shielding patterns may be alternately disposed with the bit line structures 110 in the Y-direction. A lower surface of the shielding pattern may be positioned at a level that is higher than a level of a lower surface of the lower insulating layer 101, and an upper surface of the shielding pattern may be positioned at a level that is lower than a level of an upper surface of the bit line structure 110. The shielding patterns may reduce capacitance between the bit line structures 110.

The shielding pattern may include doped polysilicon, a metal, a conductive metal nitride, a metal-semiconductor compound, a conductive metal oxide, graphene, carbon nanotubes, or combinations thereof.

The back gate structures 120 may intersect the bit line structures 110. For example, the back gate structures 120 may extend in the Y-direction, and may be spaced apart from each other in the X-direction.

The back gate structure 120 may include a back gate dielectric layer 122, a back gate electrode 124, an upper capping layer 126, and a lower capping layer 128. The back gate electrodes 124 may extend in the Y-direction, and may be spaced apart from each other in the X-direction. The back gate electrode 124 may serve to remove charges trapped in the active pattern 140. The active pattern 140 may be a floating body, and the back gate electrode 124 may be a structure for complementing the floating active pattern 140 to prevent or minimize degradation in performance of the semiconductor device 100 caused by a floating body effect of the active pattern 140.

The back gate electrode 124 may include doped polysilicon, a metal, a conductive metal nitride, a metal-semiconductor compound, a conductive metal oxide, graphene, carbon nanotubes, or combinations thereof. For example, the back gate electrode 124 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but example embodiments are not limited thereto. The back gate electrode 124 may be formed of a single layer or multiple layers that are formed of the above-described materials.

The back gate dielectric layers 122 may extend in the Y-direction along both side surfaces of the back gate electrodes 124. The back gate dielectric layers 122 may cover the both side surfaces of the back gate electrodes 124. A vertical length of the back gate dielectric layer 122 may be greater than a vertical length of the back gate electrode 124. For example, an upper surface of the back gate dielectric layer 122 may be positioned at a level that is higher than a level of an upper surface of the back gate electrode 124, and a lower surface of the back gate dielectric layer 122 may be positioned at a level that is lower than a level of a lower surface of the back gate electrode 124. In an example embodiment, the lower surface of the back gate dielectric layer 122 may be in contact with the third conductive pattern 110c. Each of the back gate dielectric layers 122 may include at least one of silicon oxide or a high-κ dielectric.

The upper capping layer 126 may be disposed on the back gate electrode 124. Side surfaces of the upper capping layer 126 may be in contact with the back gate dielectric layer 122, and an upper surface of the upper capping layer 126 may be coplanar with upper surfaces of the back gate dielectric layers 122. The upper capping layer 126 may include silicon oxide, silicon nitride, silicon oxynitride, silicon carbon nitride, a low-κ dielectric, or combinations thereof.

The lower capping layer 128 may be disposed below the back gate electrode 124. Side surfaces of the lower capping layer 128 may be in contact with the back gate dielectric layer 122, and a lower surface of the lower capping layer 128 may be coplanar with lower surfaces of the back gate dielectric layers 122. The lower capping layer 128 may include silicon oxide, silicon nitride, silicon oxynitride, silicon carbon nitride, a low-κ dielectric, or combinations thereof.

The active pattern 140 may be disposed on the bit line structure 110, and may extend in a vertical direction (e.g., a Z-direction). In a plan view, the active patterns 140 may be disposed on both side surfaces of the back gate structures 120. For example, the active patterns 140 may be disposed between the back gate structure 120 and the word line structure 150 that are adjacent to each other. The active patterns 140 may be spaced apart from each other in the X-direction and the Y-direction. An upper surface of the active pattern 140 may be coplanar with an upper surface of the back gate structure 120. A lower surface of the active pattern 140 may be in contact with the third conductive pattern 110c. It is illustrated that the lower surface of the active pattern 140 is disposed at a level in the vertical direction that is a same level as a level of the lower surface of the back gate dielectric layer 122 in the vertical direction, but example embodiments are not limited thereto. In an example embodiment, the lower surface of the active pattern 140 may be positioned at a level that is lower than a level of the lower surface of the back gate dielectric layer 122.

Each of the active patterns 140 may include a first source/drain region in contact with the bit line structure 110, a second source/drain region in contact with the contact pattern 170, and a channel region between the first source/drain region and the second source/drain region. In an example embodiment, the first and second source/drain regions may have an N-type conductivity. For example, the first and second source/drain regions may be doped with a relatively high concentration of N-type impurities, and the channel region may be doped with a relatively low concentration of P-type impurities.

In a plan view, the active pattern 140 may include a first side surface 140_S1 in contact with the back gate dielectric layer 122, and a second side surface 140_S2 in contact with the gate dielectric layer 152. In an example embodiment, the second side surface 140_S2 of the active pattern 140 may include a curved surface.

In an example embodiment, the active patterns 140 may include a single crystalline semiconductor material. The single crystalline semiconductor material may include a group IV semiconductor, a group III-V compound semiconductor, or a group II-VI compound semiconductor, for example, a single crystalline semiconductor including at least one of silicon, silicon carbide, germanium, or silicon-germanium.

However, in some example embodiments, the active patterns 140 may include at least one of a polycrystalline semiconductor material layer, an oxide semiconductor material layer such as indium gallium zinc oxide (IGZO), or a two-dimensional (2D) material layer such as MoS₂.

The oxide semiconductor layer may be indium gallium zinc oxide (IGZO). However, example embodiments are not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), manganese zinc oxide (MgZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The 2D material layer may include at least one of a transition metal dichalcogenide (TMD) material layer, a black phosphorous material layer, and a hexagonal boron-nitride (hBN) material layer, which may have semiconductor properties. For example, the 2D material layer may include at least one of BiOSe, Crl, WSe₂, MoS₂, TaS, WS, SnSe, ReS, β-SnTe, MnO, AsS, P (black), InSe, h-BN, GaSe, GaN, SrTiO, MXene, or a Janus 2D material, which may form a 2D material.

The word line structures 150 may intersect the bit line structures 110. For example, the word line structures 150 may extend in the Y-direction, and may be spaced apart from each other in the X-direction. The word line structures 150 may be alternately disposed with the back gate structure 120 in the X-direction.

The word line structure 150 may include a gate dielectric layer 152, vertical structures VS, a barrier layer 158, a support layer 160, a capping pattern 162, and an air gap AG. Each word line structure 150 may extend in the Y-direction, and may include two vertical structures VS spaced apart from each other in the X-direction.

Each of the vertical structures VS may include a word line 154, a first gate capping layer 156, and a second gate capping layer 157. The first gate capping layer 156 may be spaced apart from the second gate capping layer 157 in the vertical direction, and the word line 154 may be disposed between the first gate capping layer 156 and the second gate capping layer 157.

In a plan view, a side surface of the word line 154 may have a scallop shape. For example, the side surface of the word line 154 may include a plurality of convex curved surfaces disposed in the Y-direction. In an example embodiment, a length of the vertical structure VS in the vertical direction may be less than a length of the active pattern 140 in the vertical direction. For example, an upper surface of the vertical structure VS (an upper surface of the first gate capping layer 156) may be coplanar with an upper surface of the active pattern 140, and a lower surface of the vertical structure VS (a lower surface of the second gate capping layer 157) may be positioned at a level that is higher than a level of a lower surface of the active pattern 140. As used herein, the word line 154 may also be referred to as a “gate electrode” or a “front gate electrode.”

The word line 154 may include doped polysilicon, a metal, a conductive metal nitride, a metal-semiconductor compound, a conductive metal oxide, graphene, carbon nanotubes, or combinations thereof. For example, the word line 154 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but example embodiments are not limited thereto. The word line 154 may be formed of a single layer or multiple layers that are formed of the above-described materials. In an example embodiment, the word line 154 may be formed of a material that is the same as a material of the back gate electrode 124, but example embodiments are not limited thereto, and may include other materials.

FIG. 1 illustrates that two word lines 154 are disposed on sides of one back gate electrode 124, but example embodiments are not limited thereto. In an example embodiment, the back gate electrodes 124 may be omitted. In an example embodiment, the back gate structure 120 may be replaced with the word line structure 150. For example, in a plan view, the semiconductor device 100 may have a double gate structure in which the word lines 154 are disposed on both sides of the active pattern 140.

The first gate capping layer 156 may be in contact with an upper surface of the word line 154, and the second gate capping layer 157 may be in contact with a lower surface of the word line 154. A side surface of the first gate capping layer 156 and a side surface of the second gate capping layer 157 may be coplanar with the word line 154. The first gate capping layer 156 and the second gate capping layer 157 may include silicon oxide, silicon nitride, silicon oxynitride, silicon carbonitride, a low-κ dielectric, or combinations thereof. For example, the first gate capping layer 156 and the second gate capping layer 157 may include silicon nitride.

The gate dielectric layer 152 may extend in the Y-direction between the back gate structure 120 and the vertical structure VS, and between the active pattern 140 and the vertical structure VS. For example, the gate dielectric layer 152 may be in contact with the back gate dielectric layer 122, the word line 154, the first gate capping layer 156, the second gate capping layer 157, and the support layer 160, and may extend in the Y-direction. The gate dielectric layer 152 may also be in contact with the active patterns 140, and may partially surround the active patterns 140. The gate dielectric layer 152 may cover a side surface of the back gate dielectric layer 122 together with the active patterns 140. For example, the first side surfaces 140_S1 of the active patterns 140 may be in contact with the side surface of the back gate dielectric layer 122. The gate dielectric layer 152 may cover the second side surfaces 140_S2 of the active patterns 140, may extend in the Y-direction, and may be in contact with the side surface of the back gate dielectric layer 122 between the active patterns 140.

A length of the gate dielectric layer 152 in the vertical direction may be greater than a length of the vertical structure VS in the vertical direction. For example, an upper surface of the gate dielectric layer 152 may be coplanar with an upper surface of the vertical structure VS, and a lower surface of the gate dielectric layer 152 may be positioned at a level, lower than that of a lower surface of the vertical structure VS. In an example embodiment, the lower surface of the gate dielectric layer 152 may be in contact with the third conductive pattern 110c.

In an example, each of the gate dielectric layers 152 may be a tunnel dielectric layer, not including an information storage layer. For example, each of the gate dielectric layers 152 may include at least one of silicon oxide or a high-κ dielectric. The high-κ dielectric may include metal oxide or metal oxynitride. For example, the high-κ dielectric may be formed of HfO₂, HfSiO, HfSiON, HfTaO, HfTiO, HfZrO, ZrO₂, Al₂O₃, or combinations thereof, but example embodiments are not limited thereto. Each of the gate dielectric layers 152 may be formed of a single layer or multiple layers that are formed of the above-described materials.

In some example embodiments, each of the gate dielectric layers 152 may include an information storage layer and a dielectric layer. For example, each of the gate dielectric layers 152 may have polarization properties depending on an electric field, and may include a ferroelectric layer that may have remnant polarization caused by a dipole even in the absence of an external electric field. Data may be recorded using such a polarization state in the ferroelectric layer. Accordingly, each of the gate dielectric layers 152 may include a ferroelectric layer, which may be referred to as an information storage layer. The ferroelectric layer, which may be the information storage layer, may include an Hf-based compound, a Zr-based compound, and/or an Hf-Zr-based compound. For example, the Hf-based compound may be a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with an impurity, for example, at least one of C, Si, Mg, Al, Y, N, Ge, Sn, Gd, La, Sc, and Sr. For example, the ferroelectric layer, which may be the information storage layer, may be a material obtained by doping at least one of HfO₂, ZrO₂, or HZrO with at least one of C, Si, Mg, Al, Y, N, Ge, Sn, Gd, La, Sc, or Sr.

In the gate dielectric layers 152, the information storage layer is not limited to the above-described material types, and may include a material capable of storing information. When each of the gate dielectric layers 152 includes an information storage layer, the information storage structure 180 may be omitted.

The barrier layer 158 may cover a side surface of vertical structures VS. For example, each of the two vertical structures VS of the word line structure 150 may include a first side surface in contact with gate dielectric layers 152, and a second side surface opposite to the first side surface. The second side surfaces of the two adjacent vertical structures VS may oppose each other, and the barrier layers 158 may cover the second side surfaces of the two vertical structures VS. An upper surface of the barrier layer 158 may be coplanar with upper surfaces of the vertical structures VS. In FIG. 2, it is illustrated that a lower surface of the barrier layer 158 is coplanar with lower surfaces of the vertical structures VS, but example embodiments are not limited thereto. In a plan view, a side surface of the barrier layer 158 may have a scallop shape. For example, the side surface of the barrier layer 158 may include a plurality of convex curved surfaces disposed in the Y-direction.

The barrier layer 158 may include at least one of silicon oxide, aluminum oxide, or an amorphous carbon layer (ACL). In an example embodiment, a thickness of the barrier layer 158 may be about 0.5 nm to about 3 nm.

The support layer 160 may overlap the vertical structures VS in the vertical direction. In an example embodiment, the support layer 160 may be in contact with lower surfaces of the vertical structures VS and a lower surface of the barrier layer 158. The support layer 160 may be disposed between back gate structures 120, for example, between adjacent gate dielectric layers 152. A width of the support layer 160 in the X-direction may be greater than a width of the vertical structure VS in the X-direction. For example, a portion of the support layer 160 overlapping the active pattern 140 in the X-direction may have a horizontal width W3 in the X-direction, and a portion of the support layer 160 overlapping the capping patterns 162 in the X-direction may have a horizontal width W4 in the X-direction. The horizontal width W3 and the horizontal width W4 each may be greater than a horizontal width W5 of the vertical structure VS in the X-direction. The support layers 160 may extend in the Y-direction, and may be spaced apart from each other in the X-direction. The support layers 160 may be in contact with the bit line structure 110 and the lower insulating layer 101.

In an example embodiment, the support layer 160 may not fully fill a space between the back gate structures 120. For example, the support layer 160 may include openings OP spaced apart from each other in the Y-direction. For example, each of the openings OP may be disposed between four adjacent active patterns 140.

The support layer 160 may include external surfaces 160_S1 in contact with the gate dielectric layers 152, and internal surfaces 160_S2 exposed by the openings OP. In an example embodiment, the external surfaces 160_S1 of the support layer 160 may have recesses R. The recesses R may overlap the active patterns 140 in the X-direction. For example, as illustrated in FIG. 4, in a plan view, the support layer 160 may include first portions P1 having the external surfaces 160_S1 that are concave, and second portions P2 alternately disposed with the first portions P1 in the Y-direction. Side surfaces of the first portions P1 may have the recesses R. Side surfaces of the second portions P2 may be convex or may not have the recesses R. The first portions P1 may overlap the active patterns 140 in the X-direction. The second portions P2 may not overlap the active patterns 140 in the X-direction, and may overlap the openings OP in the X-direction. In some example embodiments, the first portions P1 may partially overlap the openings OP in the X-direction. The first portions P1 may have a horizontal width W3 in the X-direction, and the second portions P2 may have a horizontal width W4 in the X-direction.

The support layer 160 may include silicon oxide, silicon nitride, silicon oxynitride, silicon carbonitride, a low-κ dielectric, or combinations thereof. For example, the support layer 160 may include silicon oxide.

The capping patterns 162 may be disposed in the support layer 160. For example, the capping patterns 162 may be disposed in the openings OP of the support layer 160. In a plan view, side surfaces of each of the capping patterns 162 may be at least partially in contact with the internal surfaces 160_S2 of the support layer 160, and the side surfaces of each of the capping patterns 162 may be concave. Lower surfaces of the capping patterns 162 may be coplanar with a lower surface of the support layer 160. It is illustrated that upper surfaces of the capping patterns 162 are coplanar with an upper surface of the support layer 160, but example embodiments are not limited thereto. In some example embodiments, the upper surfaces of the capping patterns 162 may be disposed at a level that is different from a level of the upper surface of the support layer 160.

As illustrated in FIG. 4, in a plan view, centers C of the capping patterns 162 may be disposed to be offset from the active patterns 140 in the Y-direction. Here, the centers C of the capping patterns 162 may refer to centers of the capping patterns 162 in the X-direction and the Y-direction in the plan view. The centers C of the capping patterns 162 may overlap the first portions P1 of the support layer 160 in the X-direction.

Each of the capping patterns 162 may include silicon oxide, silicon nitride, silicon oxynitride, silicon carbonitride, a low-κ dielectric, or combinations thereof. For example, each of the capping patterns 162 may include silicon oxide, silicon nitride, silicon oxynitride, silicon oxicarbonitride, or combinations thereof.

In an example embodiment, the word line structure 150 may have an air gap AG. In an example embodiment, the air gap AG may be defined by the barrier layer 158, the support layer 160, the capping pattern 162, and the contact structure CS. For example, the air gap AG may be disposed between the two vertical structures VS, and a lower limit or a lower boundary of the air gap AG may be defined by the support layer 160 and the capping pattern 162, and an upper limit or an upper boundary of the air gap AG may be defined by the contact structure CS. A lateral limit or a lateral boundary of the air gap AG may be defined by the barrier layer 158. According to example embodiments, the air gap AG may be formed between the word lines 154, such that electrical coupling between the word lines 154 may be prevented or reduced. The air gap AG may extend in the Y-direction. In an example embodiment, a horizontal width of the air gap AG in the X-direction may not be constant. For example, the horizontal width of the air gap AG in the X-direction may repeatedly increase and decrease in the Y-direction. For example, at a point not overlapping the active patterns 140 in the X-direction, the air gap AG may have a maximum horizontal width W1, and at a point overlapping the active patterns 140 in the X-direction, the air gap AG may have a minimum horizontal width W2. Points at which the air gap AG has the maximum horizontal width W1 and points at which the air gap AG has the minimum horizontal width W2 may be alternately disposed in the Y-direction.

The word line structure 150 according to example embodiments may have an open upper surface or lower surface. For example, the upper surface of the word line structure 150 may be open, and the air gap AG may expose an insulating structure 175 of the contact structure CS.

The contact structure CS may be disposed on upper surfaces of the active patterns 140. The contact structure CS may include contact patterns 170 and an insulating structure 175. The contact patterns 170 may be in contact with the upper surfaces of the active patterns 140, and may be electrically connected to the active patterns 140. Lower surfaces of the contact patterns 170 may be in contact with the back gate dielectric layer 122, the active pattern 140, and the gate dielectric layer 152. The contact patterns 170 may electrically connect the active patterns 140 and the information storage structure 180 to each other.

The contact patterns 170 may include a conductive material, for example, doped single crystalline silicon, doped polycrystalline silicon, a metal, a conductive metal nitride, a metal-semiconductor compound, a conductive metal oxide, conductive graphene, carbon nanotubes, or combinations thereof. In an example embodiment, the contact patterns 170 may include a first contact layer 170a, a second contact layer 170b, a third contact layer 170c, and a fourth contact layer 170d, sequentially stacked. For example, the first contact layer 170a may include undoped polycrystalline silicon, the second contact layer 170b may include doped polycrystalline silicon, the third contact layer 170c may include a silicide material, and the fourth contact layer 170d may include a metal. However, in some example embodiments, the number of layers of the contact patterns 170 and a type of material of the layers may be changed in various manners.

The insulating structure 175 may vertically extend, and may be in contact with at least one of the back gate dielectric layer 122, the upper capping layer 126, the gate dielectric layer 152, and the first gate capping layer 156. The insulating structure 175 may spatially separate the contact patterns 170 from each other, and may electrically insulate the contact patterns 170 from each other. The insulating structure 175 may include silicon oxide, silicon nitride, silicon oxynitride, silicon carbonitride, a low-κ dielectric, or combinations thereof. For example, the insulating structure 175 may include silicon nitride.

The information storage structure 180 may include first electrodes 182 electrically connected to the contact patterns 170, second electrodes 186 covering the first electrodes 182, and a dielectric layer 184 between the first electrodes 182 and the second electrode 186.

In an example embodiment, the information storage structure 180 may be a capacitor storing information in DRAM. For example, the dielectric layer 184 of the information storage structure 180 may be a capacitor dielectric layer of the DRAM, and the dielectric layer 184 may include a high-κ dielectric, silicon oxide, silicon nitride, silicon oxynitride, or combinations thereof.

In some example embodiments, the information storage structure 180 may be used for an memory different from the DRAM. For example, the dielectric layer 184 of the information storage structure 180 may be a capacitor dielectric layer of a ferroelectric memory (FeRAM). In this case, the dielectric layer 184 may be a ferroelectric layer capable of recording data using a polarization state. In some example embodiments, the dielectric layer 184 may include a lower dielectric layer including at least one of silicon oxide or a high-κ dielectric, and a ferroelectric layer disposed on the lower dielectric layer.

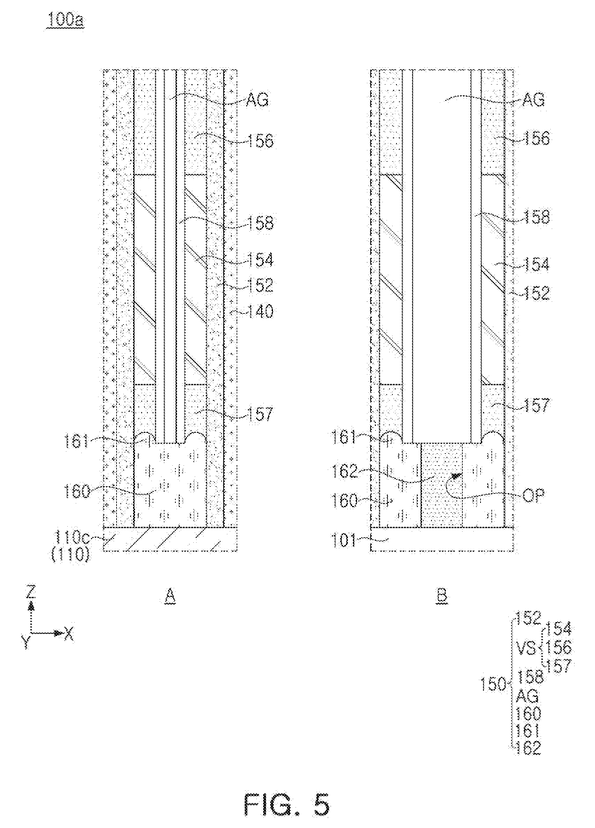

FIGS. 5-9 are longitudinal cross-sectional views of semiconductor devices according to example embodiments. In FIGS. 5-9, the same reference designators are used for the same components described above and repeated description thereof is omitted for conciseness.

Referring to FIG. 5, a word line structure 150 of a semiconductor device 100a may include the support layer 160 overlapping vertical structures VS in a vertical direction. In an example embodiment, the support layer 160 may include protrusions 161 protruding in the vertical direction toward the vertical structures VS. For example, the protrusions 161 may extend from an upper surface of the support layer 160, and may be in contact with second gate capping layers 157. Upper surfaces of the protrusions 161 may be convex, and lower surfaces of the second gate capping layers 157 may be concave.

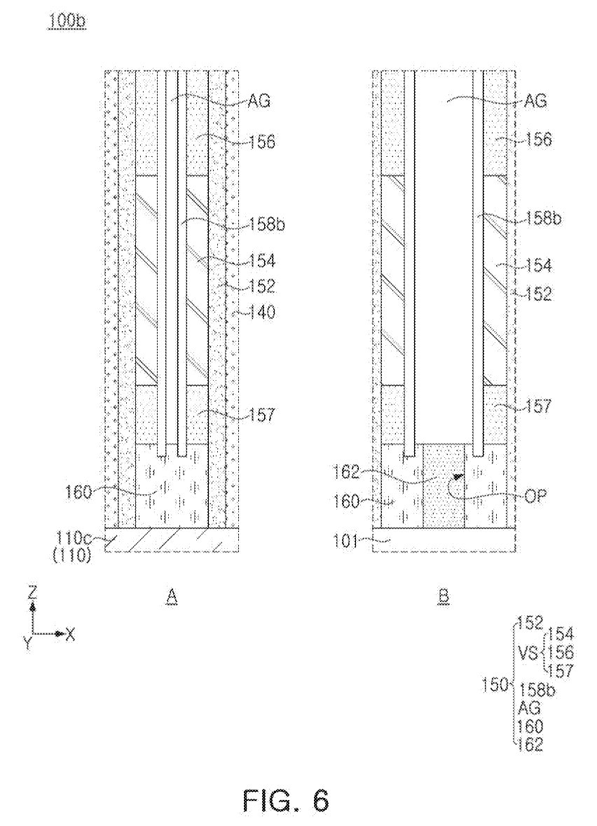

Referring to FIG. 6, a word line structure 150 of a semiconductor device 100b may include barrier layers 158b covering side surfaces of vertical structures VS. In an example embodiment, the barrier layers 158b may extend in a vertical direction, and may partially pass through the support layer 160. For example, the barrier layers 158b may extend into the support layer 160. For example, lower surfaces of the barrier layers 158b may be disposed at a level that is lower than a level of lower surfaces of the second gate capping layers 157 and that of an upper surface of the support layer 160.

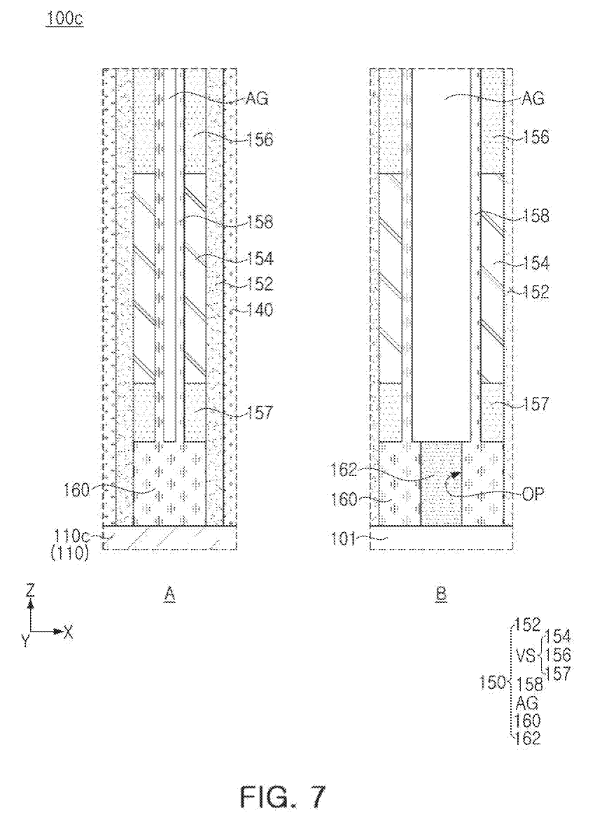

Referring to FIG. 7, a word line structure 150 of a semiconductor device 100c may include barrier layers 158 covering side surfaces of vertical structures VS. In an example embodiment, the barrier layers 158 may be integrally formed with the support layer 160. For example, the barrier layers 158 may include a material that is the same as a material of the support layer 160, and an interface between the barrier layers 158 and the support layer 160 may not be observed.

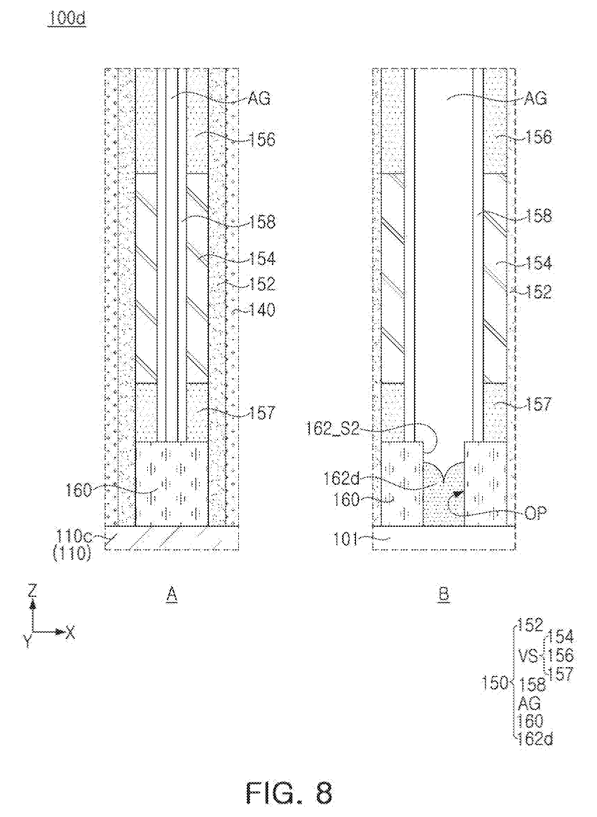

Referring to FIG. 8, a word line structure 150 of a semiconductor device 100d may include the support layer 160 overlapping vertical structures VS in a vertical direction, and a capping pattern 162d disposed in an opening OP of the support layer 160. In an example embodiment, the capping pattern 162d may partially fill the opening OP of the support layer 160. For example, an upper portion of an internal surface 160_S2 of the support layer 160 may not be covered by the capping pattern 162d, and may be exposed by the air gap AG. For example, the air gap AG may overlap a portion of the support layer 160 in a horizontal direction. A length of the capping pattern 162d in the vertical direction may be less than a length of the support layer 160 in the vertical direction.

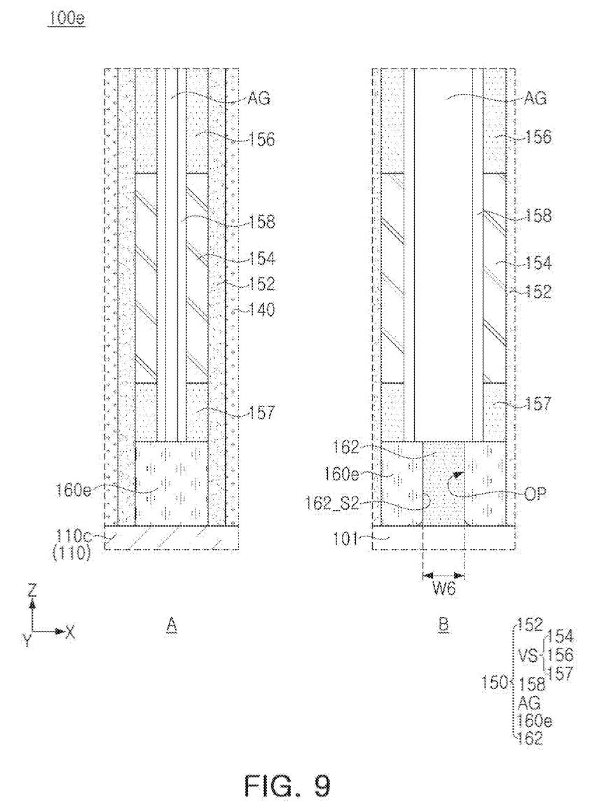

Referring to FIG. 9, a word line structure 150 of a semiconductor device 100e may include a support layer 160e overlapping vertical structures VS in a vertical direction, and the capping pattern 162 disposed in an opening OP of the support layer 160e. In an example embodiment, in a longitudinal cross-sectional view, internal surfaces 160_S2 of the support layer 160e may respectively include a curved surface. For example, a horizontal width W6 of the capping pattern 162 in an X-direction may increase as a distance from a contact structure CS and an air gap AG increases (see FIG. 2). A horizontal width of a lower surface of the capping pattern 162 in the X-direction may be greater than a horizontal width of an upper surface of the capping pattern 162 in the X-direction. For example, the horizontal width W6 of the capping pattern 162 may increase from the upper surface toward the lower surface.

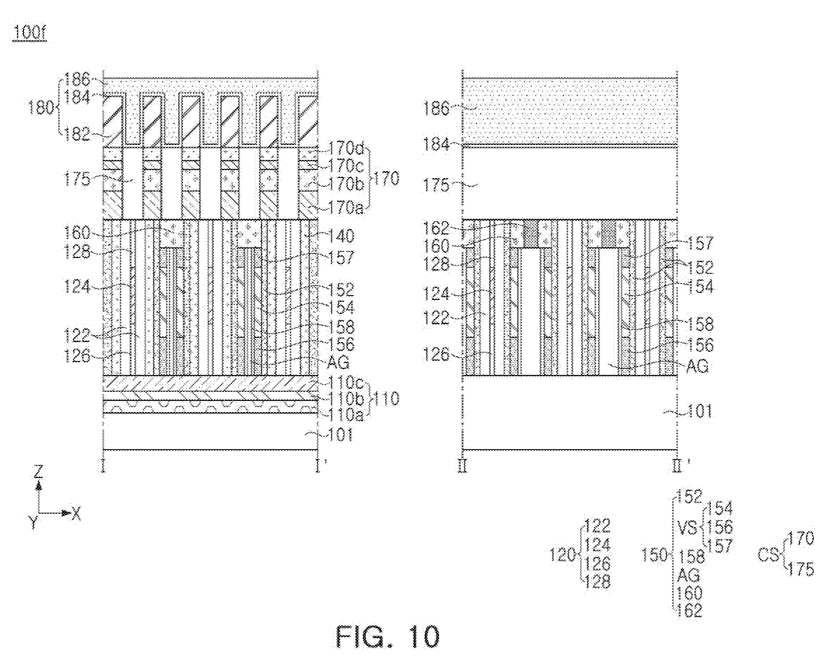

FIG. 10 is a longitudinal cross-sectional view of a semiconductor device according to an example embodiment.

Referring to FIG. 10, a semiconductor device 100f may include a bit line structure 110 connected to active patterns 140, the bit line structure 110 overlapping the active patterns 140 in a vertical direction, a contact structure CS, and an information storage structure 180. In an example embodiment, a support layer 160 and capping patterns 162 may be in contact with the contact structure CS. For example, an upper surface of the support layer 160 and upper surfaces of the capping patterns 162 may be in contact with an insulating structure 175. The support layer 160 and the capping patterns 162 may define an upper limit or an upper boundary of an air gap AG.

In an example embodiment, the word line structure 150 may have an open upper surface or lower surface. For example, the lower surface of the word line structure 150 may be open, and the air gap AG may expose upper surfaces of the bit line structure 110 and a lower insulating layer 101. The bit line structure 110 and the lower insulating layer 101 may define a lower limit or a lower boundary of the air gap AG.

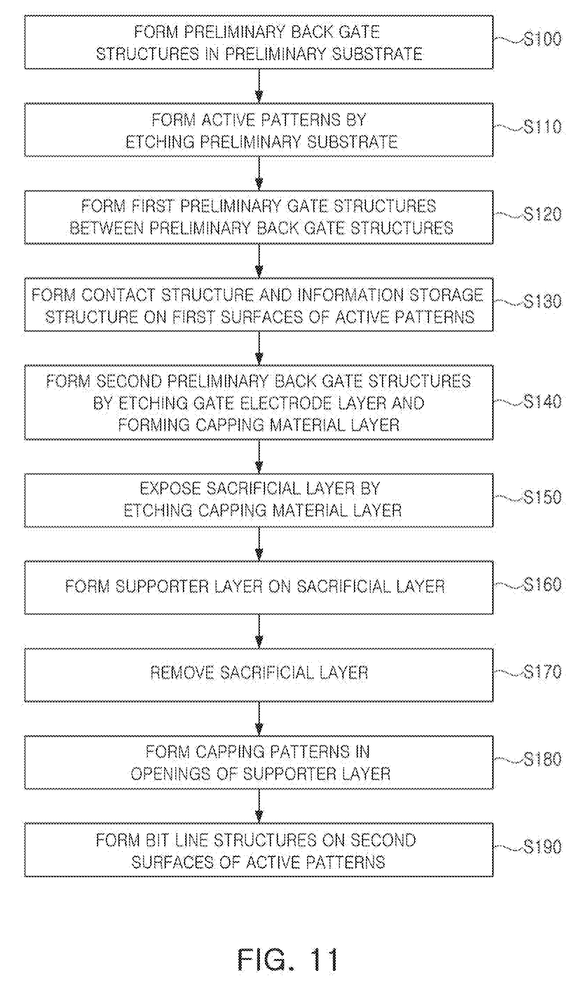

FIG. 11 is a flowchart of a method of manufacturing a semiconductor device according to an example embodiment.

Referring to FIG. 11, a method of manufacturing a semiconductor device according to an example embodiment may include forming preliminary back gate structures in a preliminary substrate (S100), forming active patterns by etching the preliminary substrate (S110), forming first preliminary gate structures between the preliminary back gate structures (S120), forming a contact structure and an information storage structure on first surfaces of the active patterns (S130), forming a capping material layer and forming second preliminary gate structures by etching a gate electrode layer (S140), exposing a sacrificial layer by etching the capping material layer (S150), forming a support layer on the sacrificial layer (S160), removing the sacrificial layer (S170), forming capping patterns in openings of the support layer (S180), and forming bit line structures on second surfaces of the active patterns (S190).

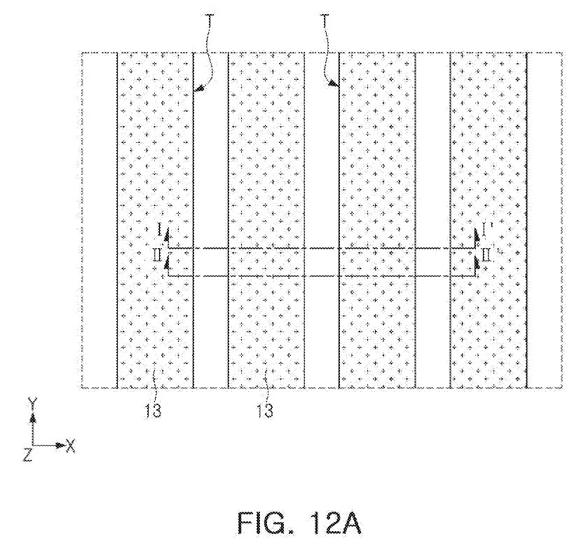

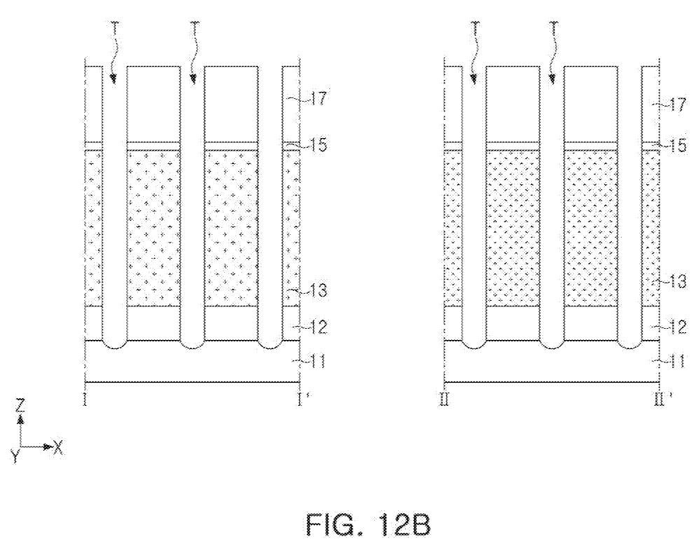

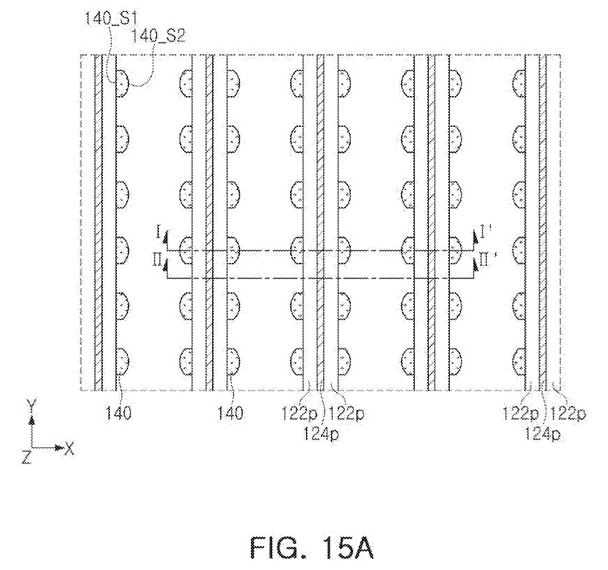

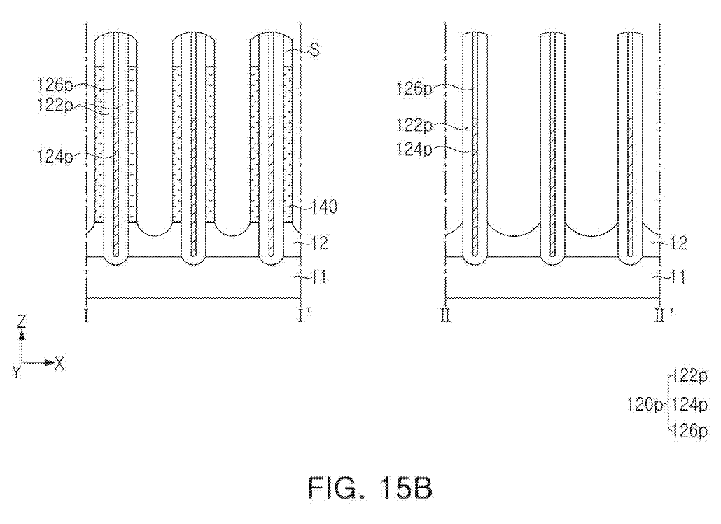

FIGS. 12A, 12B, 13A, 13B, 14A, 14B, 15A, 15B, 16A, 16B, 17, 18, 19, 20A, 20B, 21A, 21B, 22, 23A, and 23B, are plan views and longitudinal cross-sectional views of sequential processes in a method of manufacturing a semiconductor device according to an example embodiment.

Specifically, FIGS. 12A, 13A, 14A, 15A, 16A,20A,21A and 23A, are plan views corresponding to FIG. 1. FIGS. 12B, 13B, 14B, 15B, 16B, 17B, 18, 19, 20B, 21B, 22, and 23B, are longitudinal cross-sectional views corresponding to FIG. 2.

Referring to FIGS. 12A and 12B, a lower substrate 11, an intermediate layer 12, and a preliminary substrate 13 may be provided. The lower substrate 11, the intermediate layer 12, and the preliminary substrate 13 may be stacked in a vertical direction, and the intermediate layer 12 may be disposed between the lower substrate 11 and the preliminary substrate 13.

In an example embodiment, the lower substrate 11 and the preliminary substrate 13 may be semiconductor material layers, and the intermediate layer 12 may be an insulating layer. For example, the lower substrate 11, the intermediate layer 12, and the preliminary substrate 13 may be silicon on insulator (SOI) substrates, and the lower substrate 11 and the preliminary substrate 13 may include single crystalline silicon. In an example embodiment, the lower substrate 11, the intermediate layer 12, and the preliminary substrate 13 may be semiconductor material layers, and the intermediate layer 12 and the preliminary substrate 13 may be formed on the lower substrate 11 by a deposition method or an epitaxial growth method. In an example embodiment, the preliminary substrate 13 may be a bulk silicon substrate, and the lower substrate 11 and the intermediate layer 12 may be omitted.

A buffer layer 15 and a mask layer 17 may be formed on the preliminary substrate 13. The buffer layer 15 and the mask layer 17 may respectively include silicon oxide, silicon nitride, silicon oxynitride, silicon carbonitride, a low-κ dielectric, or combinations thereof. The buffer layer 15 may include a material different from that of the mask layer 17. For example, the buffer layer 15 may include silicon oxide, and the mask layer 17 may include silicon nitride. The buffer layer 15 and the mask layer 17 illustrated in FIG. 12B are exemplary and are not limited thereto. In an example embodiment, a single buffer layer may be formed on the preliminary substrate 13.

Trenches T may be formed by an anisotropic etching process using the mask layer 17 as an etching mask. For example, the trenches T may be formed by etching the intermediate layer 12, the preliminary substrate 13, the buffer layer 15, and the mask layer 17. The trenches T may extend in a Y-direction, and may be spaced apart from each other in an X-direction. The trenches T may expose internal surfaces of the preliminary substrate 13, internal surfaces of the intermediate layer 12, and an upper surface of the lower substrate 11.

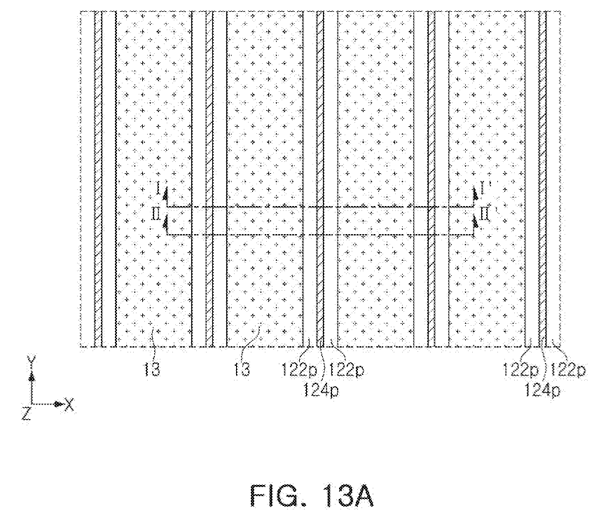

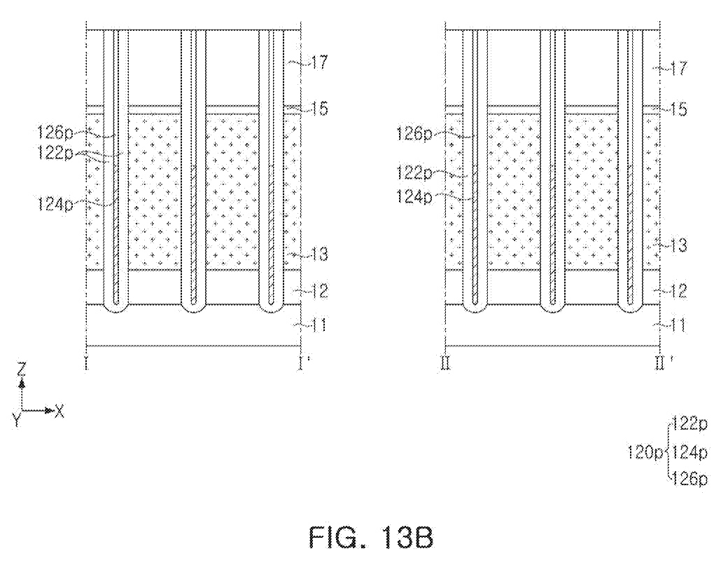

Referring to FIGS. 11, 13A and 13B, preliminary back gate structures 120p may be formed in the preliminary substrate 13 (S100). For example, the preliminary back gate structures 120p may be formed by forming dielectric material layers 122p, back gate electrode layers 124p, and preliminary capping layers 126p in the trenches T. The dielectric material layers 122p may be formed on inner walls of the trenches T. The back gate electrode layers 124p may be formed by depositing an electrode material layer on the dielectric material layers 122p and etching back the electrode material layer. The back gate electrode layers 124p may not fully fill the trenches T, and upper surfaces of the back gate electrode layers 124p may be disposed at a level, lower than that of upper surfaces of the mask layer 17.

After forming an insulating material layer on the back gate electrode layers 124p, the insulating material layer may be planarized to expose an upper surface of the mask layer 17, such that the preliminary capping layers 126p may be formed. For example, the planarization process may be performed through a chemical mechanical polishing (CMP) process. The preliminary capping layers 126p may be coplanar with the upper surface of the mask layer 17. The preliminary back gate structures 120p may be formed along the trenches T. The preliminary back gate structures 120p may extend in the Y-direction, and may be spaced apart from each other in the X-direction.

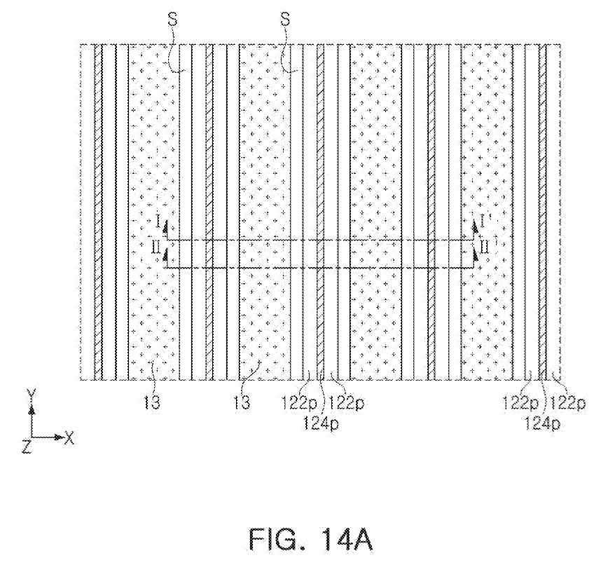

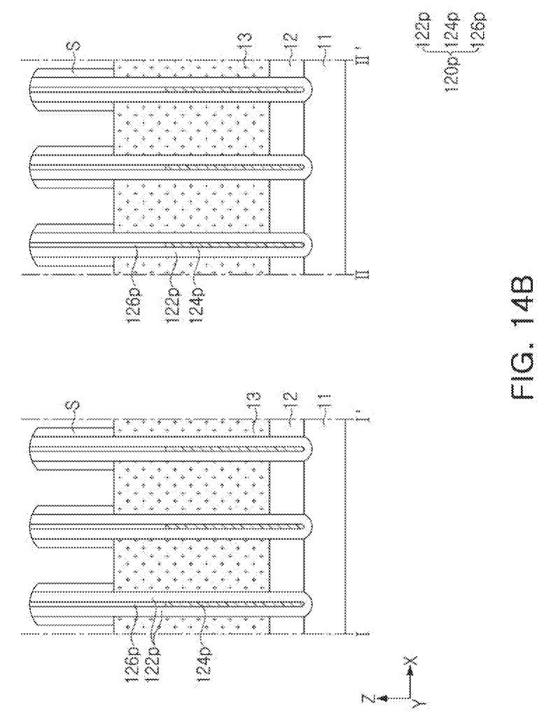

Referring to FIGS. 14A and 14B, the mask layer 17 may be removed, and side surfaces of the preliminary back gate structures 120p may be partially exposed. After forming an insulating material layer to cover the preliminary back gate structures 120p, spacer layers S may be formed by anisotropically etching the insulating material layer. The spacer layers S may be disposed on the preliminary substrate 13, and may be disposed on the side surfaces of the preliminary back gate structures 120p. In the anisotropic etching process, the buffer layer 15 may be removed, and an upper surface of the preliminary substrate 13 may be exposed. The spacer layers S may include silicon oxide, silicon nitride, silicon oxynitride, silicon carbonitride, a low-κ dielectric, or combinations thereof. For example, the spacer layers S may include silicon oxide.

Referring to FIGS. 11 and 15A-16B , active patterns 140 may be formed by etching the preliminary substrate 13 (S110). The formation of the active patterns 140 by etching the preliminary substrate 13 may include forming preliminary active patterns by etching the preliminary substrate 13 through an anisotropic etching process using the spacer layers S as an etching mask, and forming the active patterns 140 by etching the preliminary active patterns.

The active patterns 140 may be disposed between the preliminary back gate structures 120p, and may be spaced apart from each other in the X-direction and the Y-direction.

In an example embodiment, in a plan view, a side surface of the active pattern 140 may be rounded. For example, each of the active patterns 140 may include first side surfaces 140_S1 in contact with the preliminary back gate structures 120p, and second side surfaces 140_S2 opposite to the first side surfaces 140_S1. The second side surfaces 140_S2 of the active patterns 140 may include a curved surface.

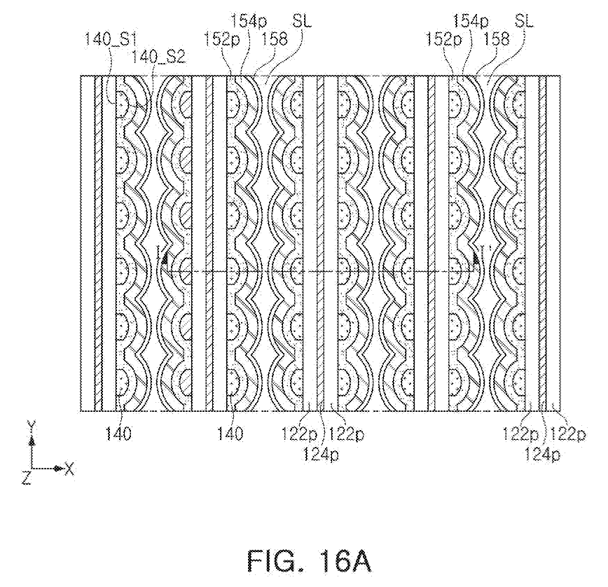

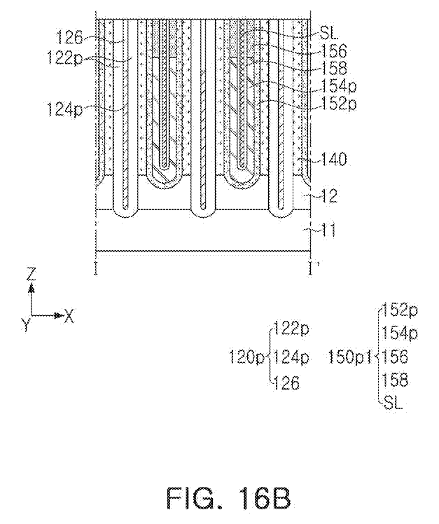

Referring to FIGS. 11, 16A, and 16B, first preliminary gate structures 150p1 may be formed between the preliminary back gate structures 120p (S120). The first preliminary gate structures 150p1 may extend in the Y-direction, and may be spaced apart from each other in the X-direction. Each of the first preliminary gate structures 150p1 may include a dielectric material layer 152p, a gate electrode layer 154p, a first gate capping layer 156, a barrier layer 158, and a sacrificial layer SL. First, gate trenches extending in the Y-direction, the gate trenches spaced apart from each other in the X-direction, may be formed between the preliminary back gate structures 120p. A dielectric material layer 152p may be formed on each of the gate trenches, and a gate electrode layer 154p may be formed on the dielectric material layer 152p.

The barrier layer 158 and the sacrificial layer SL may be formed on the gate electrode layer 154p. The gate electrode layer 154p, the barrier layer 158, and the sacrificial layer SL may fill the gate trench. After etching back the gate electrode layer 154p, an insulating material layer may be filled in a space from which a portion of the gate electrode layer 154p is removed, and a planarization process may be performed to expose the active patterns 140. The first preliminary gate structures 150p1 may be coplanar with the active patterns 140 and the preliminary back gate structures 120p. For example, the dielectric material layers 152p and the first gate capping layers 156 may be coplanar with the active patterns 140 and the preliminary back gate structures 120p.

The sacrificial layer SL may include silicon oxide, silicon nitride, silicon oxynitride, silicon carbonitride, a low-κ dielectric, or combinations thereof. For example, the sacrificial layer SL may include silicon nitride. The barrier layer 158 may include a material having an etch selectivity with respect to the sacrificial layer SL. For example, the barrier layer 158 may include at least one of silicon oxide, aluminum oxide, and an ACL.

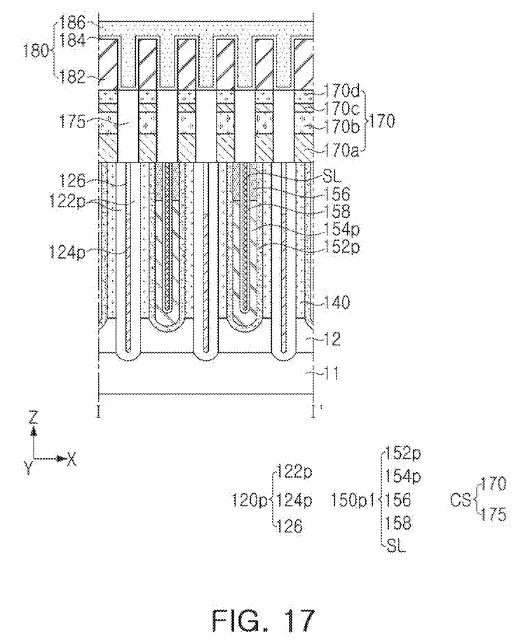

Referring to FIGS. 11, and 17, a contact structure CS and an information storage structure 180 may be formed on upper surfaces of the active patterns 140 (S130). The contact structure CS may include contact patterns 170 and an insulating structure 175 between the contact patterns 170. As used herein, upper surfaces and lower surfaces of the active patterns 140 may be referred to as first surfaces and second surfaces of the active patterns 140, respectively.

Each of the contact patterns 170 may include a first contact pattern 170a, a second contact pattern 170b, a third contact pattern 170c, and a fourth contact pattern 170d, sequentially stacked. The contact patterns 170 may be electrically connected to the active patterns 140. In an example embodiment, the contact patterns 170 may be formed by stacking conductive layers on the active patterns 140, and patterning the conductive layers. The insulating structure 175 may be formed by filling an insulating material layer in a space between the contact patterns 170.

The information storage structure 180 including first electrodes 182, a dielectric layer 184, and a second electrode 186 may be formed on the contact patterns 170. The first electrodes 182 may be in contact with the fourth contact patterns 170d of the contact patterns 170.

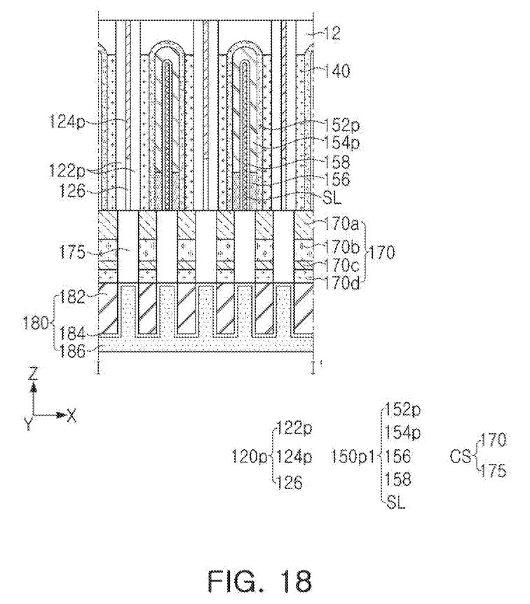

Referring to FIG. 18, a resulting structure of FIG. 17 may be inverted such that the information storage structure 180 faces a lower portion of a lower substrate 111, and the lower substrate 11 may be removed. For example, the lower substrate 11 may be removed by a grinding process, and the preliminary back gate structures 120p may be partially etched. The dielectric material layers 122p and the back gate electrode layers 124p of the preliminary back gate structures 120p may be exposed.

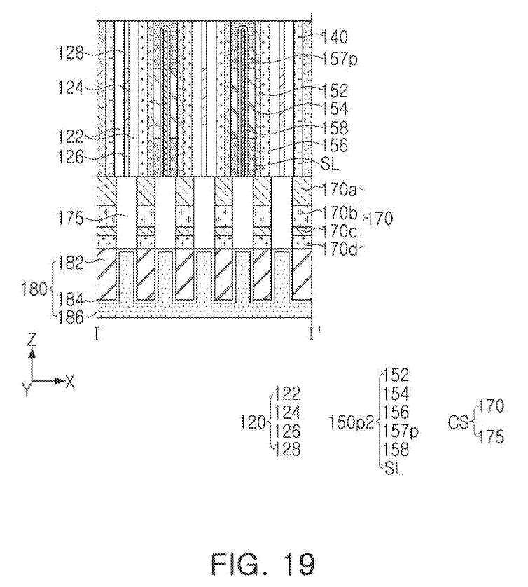

Referring to FIGS. 11 and 19, a capping material layer 157p may be formed by etching the gate electrode layer 154p to form second preliminary gate structures 150p2 (S140). For example, back gate electrodes 124 may be formed by etching back the exposed back gate electrode layers 124p, and an insulating material layer may be filled in a space from which the back gate electrode layers 124p are removed. A planarization process may be performed to expose the active patterns 140, and a back gate dielectric layer 122 and a lower capping layer 128 may be formed by etching the dielectric material layers 122p and the insulating material layer, respectively. The back gate dielectric layer 122, the back gate electrode 124, the upper capping layer 126, and the lower capping layer 128 may be included in a back gate structure 120.

By the planarization process, the first preliminary gate structures 150p1 may be partially etched. For example, gate dielectric layers 152 may be formed and gate electrode layers 154p may be exposed by etching the dielectric material layers 152p of the first preliminary gate structures 150p1. Word lines 154 may be formed by etching back the gate electrode layers 154p. An insulating material layer, covering the word lines 154 and barrier layers 158, may be formed, and the insulating material layer may be planarized to expose the active patterns 140, such that the capping material layer 157p may be formed. The gate dielectric layer 152, the word line 154, the first gate capping layer 156, the capping material layer 157p, the barrier layer 158, and the sacrificial layer SL may be included in a second preliminary gate structure 150p2. The capping material layer 157p may extend in the Y-direction along the word line 154.

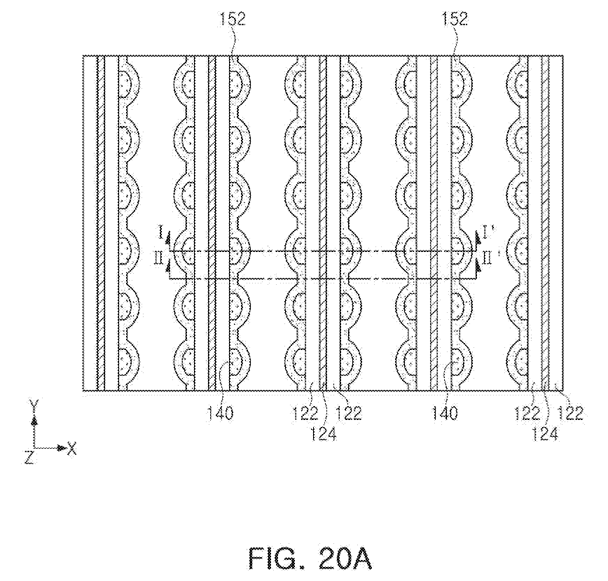

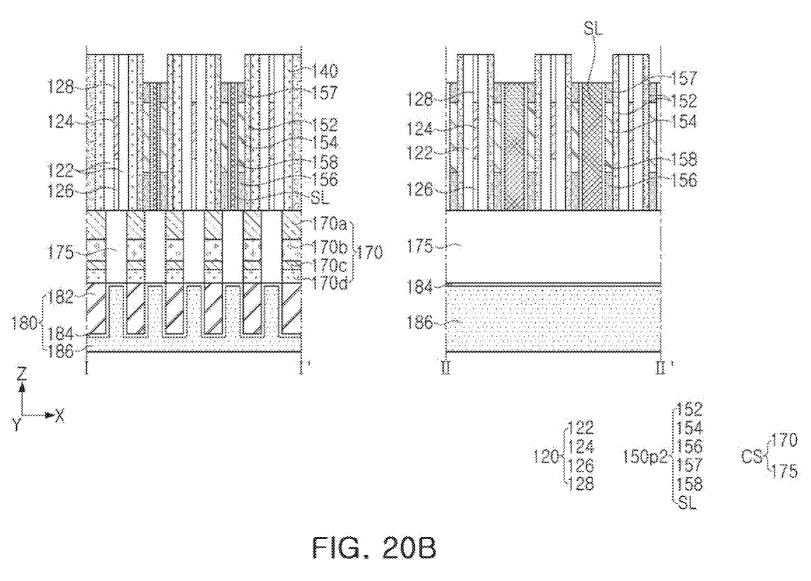

Referring to FIGS. 11, 20A, and 20B, the sacrificial layer SL may be exposed by etching the capping material layer 157p (S150). For example, the capping material layer 157p, the sacrificial layer SL, and the barrier layer 158 may be etched by a stripping process. Side surfaces of the gate dielectric layers 152 may be exposed. A second gate capping layer 157 may be formed by etching the capping material layer 157p. It is illustrated that the second gate capping layer 157, the sacrificial layer SL, and the barrier layer 158 are coplanar with each other, but example embodiments are not limited thereto. In an example embodiment, an etch rate of the barrier layer 158 may be different from those of the second gate capping layer 157 and the sacrificial layer SL, and the barrier layer 158 may not be coplanar with the second gate capping layer 157 and the sacrificial layer SL. In an example embodiment, surfaces of the exposed second gate capping layer 157 and the sacrificial layer SL may include a curved surface.,

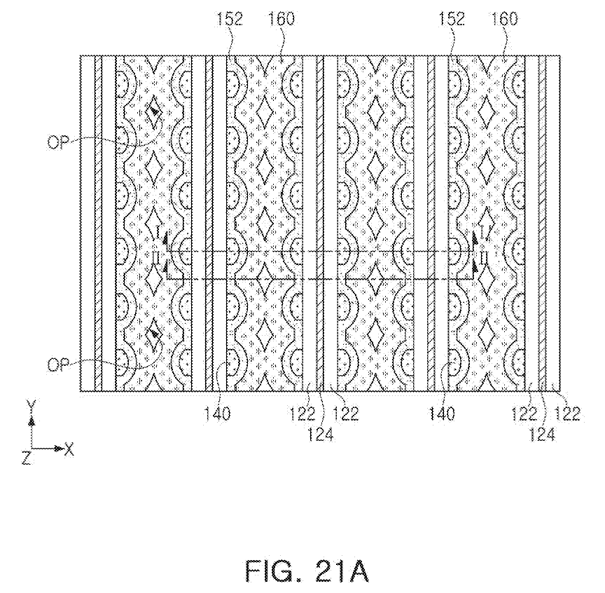

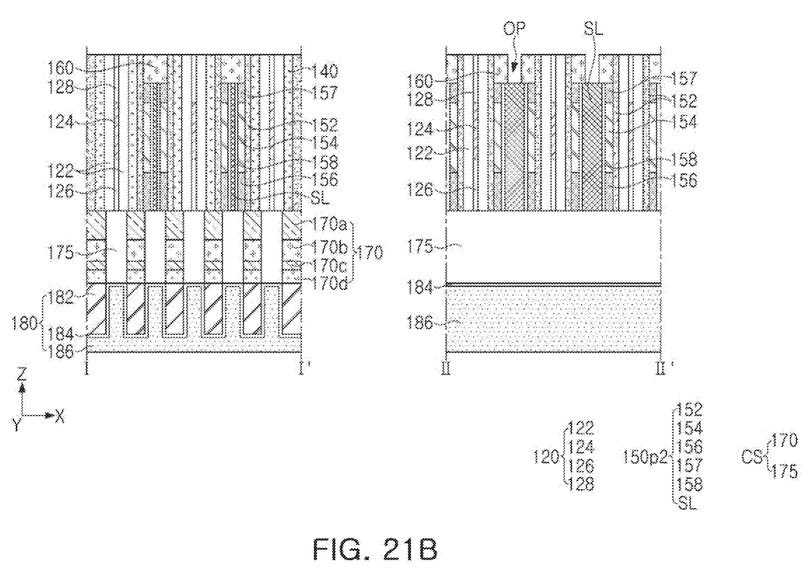

Referring to FIGS. 11, 21A, and 21B, a support layer 160 may be formed on the sacrificial layer SL (S160). For example, the support layer 160 may cover the second gate capping layer 157, the sacrificial layer SL, and the barrier layer 158. The support layer 160 may be disposed between back gate structures 120, for example, between adjacent gate dielectric layers 152. The support layers 160 may extend in the Y-direction, and may be spaced apart from each other in the X-direction.

In an example embodiment, the support layer 160 may not entirely cover the sacrificial layer SL. For example, the support layer 160 may include openings OP spaced apart from each other in the Y-direction. In a plan view, centers of the openings OP may be disposed to be offset from the active patterns 140 in the Y-direction. For example, each of the openings OP may be disposed between four adjacent active patterns 140.

The support layer 160 may include silicon oxide, silicon nitride, silicon oxynitride, silicon carbonitride, a low-κ dielectric, or combinations thereof. The support layer 160 may include a material having an etch selectivity with respect to the sacrificial layer SL. For example, the support layer 160 may include silicon oxide.

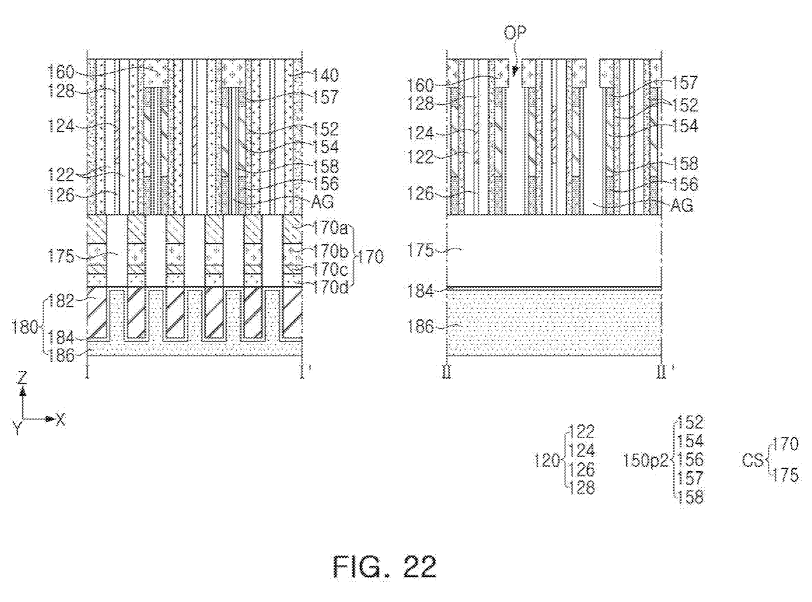

Referring to FIGS. 11, and 22, the sacrificial layer SL may be removed (S170). For example, the sacrificial layer SL may be removed through the openings OP of the support layer 160. The barrier layer 158 and the support layer 160 include a material having an etch selectivity with respect to the sacrificial layer SL, and thus may not be removed. The support layer 160 may be disposed between the back gate structures 120, thereby preventing or reducing warpage of the back gate structures 120 during a removal process of the sacrificial layer SL.

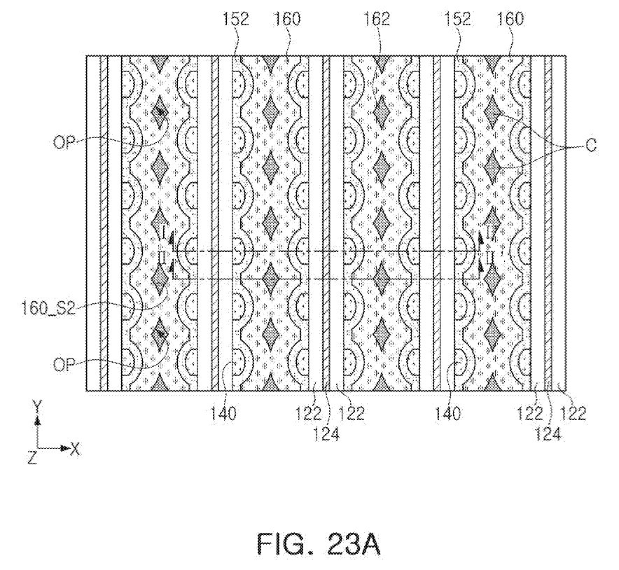

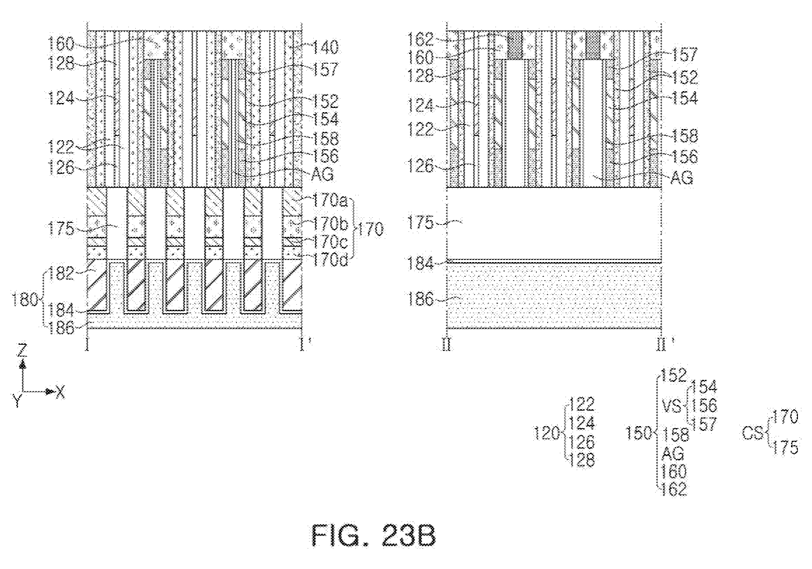

Referring to FIGS. 11, 23A, and 23B, capping patterns 162 may be formed in the openings OP of the support layer 160 (S180). For example, an insulating material layer may be formed to cover the back gate structures 120 and the active patterns 140 and to at least partially fill the openings OP, and the insulating material layer may be planarized to expose the active patterns 140, such that the capping patterns 162 may be formed. The insulating material layer may be formed using a process with low step coverage, such as a chemical vapor deposition (CVD) process. Accordingly, the capping patterns 162 may fill the openings OP. However, a space between the barrier layers 158 may not be fully filled. In an example embodiment, the capping patterns 162 may partially fill the openings OP.

The gate dielectric layer 152, the word line 154, the first gate capping layer 156, the second gate capping layer 157, the barrier layer 158, the support layer 160, and the capping pattern 162 may be included in a word line structure 150. The word line structure 150 may have an air gap AG therein. For example, the air gap AG may be formed in a space from which the sacrificial layer SL is removed. The barrier layer 158, the support layer 160, the capping pattern 162, and the contact structure CS may define the air gap AG.

As illustrated in FIG. 22, 23A and 23B, the air gap AG may be formed by sealing the space from which the sacrificial layer SL is removed with the capping pattern 162, such that the air gap AG may be relatively easily formed. For example, according to the present inventive concept, the air gap AG may be formed by covering the openings OP having a size smaller than that of the support layer 160, such that the capping pattern 162 defining the air gap AG may be easily formed. In addition, although the sacrificial layer SL is removed, the support layer 160 may support the back gate structures 120, thereby preventing or reducing warpage of the back gate structures 120. In addition, as illustrated in FIGS. 16A and 16B, the barrier layer 158 covering the gate electrode layer 154p may be formed after the gate electrode layer 154p is formed, thereby preventing oxidation of the word line 154 due to natural oxidation. Accordingly, an increase in resistance of the word line 154 may be prevented, and degradation in electrical properties of the word line 154 may be prevented.

Referring to FIGS. 11 and 1-4, a lower insulating layer 101 and bit line structures 110 may be formed on lower surfaces of the active patterns 140 (S190).

The bit line structures 110 and the lower insulating layer 101 may be formed on the lower surfaces of the active patterns 140 (S190), such that a semiconductor device 100 may be manufactured. The bit line structure 110 may include a third conductive pattern 110c, a second conductive pattern 110b, and a first conductive pattern 110a, sequentially stacked on the active patterns 140.

According to still yet another aspect of one or more embodiments, there is provided a method of manufacturing a semiconductor device, the method including forming preliminary back gate structures extending in a first horizontal direction in a preliminary substrate, forming active patterns by etching the preliminary substrate, forming first preliminary gate structures between the preliminary back gate structures, the first preliminary gate structures respectively including a gate electrode layer, a barrier layer on the gate electrode layer, and a sacrificial layer on the barrier layer, forming word lines by etching the gate electrode layers of the first preliminary gate structures, and forming second preliminary gate structures by forming capping material layers on the word lines, exposing sacrificial layers by etching the capping material layers, forming support layers including openings on the sacrificial layers, removing the sacrificial layers, and forming capping patterns in the openings of the support layers. An air gap may be formed between the word lines.

In an example embodiment, the method may further include forming a contact structure on first surfaces of the active patterns and an information storage structure on the contact structure, before forming the second preliminary gate structures.

In an example embodiment, the method may further include forming bit line structures on second surfaces of the active patterns opposite to the first surfaces, after forming the capping patterns.

In an example embodiment, the contact structure may define an upper limit of the air gap.

In an example embodiment, the support layer and the capping material layers may define a lower limit of the air gap.

In an example embodiment, the barrier layer may define a lateral limit of the air gap.

In an example embodiment, the openings may be spaced apart from each other in the first horizontal direction.

In an example embodiment, the capping patterns may partially fill the openings.

In an example embodiment, the air gap may extend in the second horizontal direction.

In an example embodiment, centers of the capping patterns may be disposed to be offset from the active pattern in the first horizontal direction.

According to various example embodiments, an air gap may be formed between word lines, such that electrical coupling between the word lines may be prevented or reduced. The air gap may be formed by sealing a space from which a sacrificial layer is removed with a capping pattern, such that the air gap may be relatively easily formed.

While various example embodiments have been shown and described above, it will be apparent to those skilled in the art that modifications and variations could be made without departing from the scope of the present disclosure as defined by the appended claims.

What is claimed is:

1. A semiconductor device comprising:
an active pattern including a first side surface and a second side surface opposite to the first side surface, the active pattern extending in a vertical direction;
a bit line structure in contact with a lower surface of the active pattern;
a contact structure in contact with an upper surface of the active pattern; and
a word line structure in contact with the second side surface of the active pattern, the word line structure extending in a first horizontal direction,
wherein the word line structure includes:
vertical structures spaced apart from each other in a second horizontal direction that intersects the first horizontal direction, the vertical structures including word lines;
a support layer in contact with lower surfaces of the vertical structures; and
an air gap between the vertical structures, and
wherein the contact structure is exposed by the air gap.

2. The semiconductor device of claim 1, wherein:
the word line structure further includes barrier layers on side surfaces of the vertical structures, and
the barrier layers are exposed by the air gap.

3. The semiconductor device of claim 2, wherein a thickness of each of the barrier layers is about 0.5 nm to about 3 nm.

4. The semiconductor device of claim 2, wherein the barrier layers include at least one of silicon oxide, aluminum oxide, or an amorphous carbon layer.

5. The semiconductor device of claim 2, wherein
the barrier layers extend into the support layer, and
lower surfaces of the barrier layers are disposed at a level that is lower than a level of an upper surface of the support layer.

6. The semiconductor device of claim 2, wherein the barrier layers are integrally formed with the support layer.

7. The semiconductor device of claim 1, wherein a width of the support layer in the second horizontal direction is greater than a width of each of the vertical structures in the second horizontal direction.

8. The semiconductor device of claim 1, wherein:
the support layer defines a lower limit of the air gap, and
the contact structure defines an upper limit of the air gap.

9. The semiconductor device of claim 1, wherein the vertical structures further include first gate capping layers in contact with lower surfaces of the word lines and second gate capping layers in contact with upper surfaces of the word lines.

10. The semiconductor device of claim 9, wherein:
the first gate capping layers are in contact with the support layer, and
the second gate capping layers are in contact with the contact structure.

11. The semiconductor device of claim 1, wherein the air gap extends in the first horizontal direction.

12. The semiconductor device of claim 1, wherein the support layer includes protrusions that protrude toward the vertical structures.

13. A semiconductor device comprising:
an active pattern including a first side surface and a second side surface opposite to the first side surface, the active pattern extending in a vertical direction;
a bit line structure in contact with a lower surface of the active pattern;
a contact structure in contact with an upper surface of the active pattern;
a back gate structure in contact with the first side surface of the active pattern, the back gate structure extending in a first horizontal direction and including a back gate electrode; and
a word line structure in contact with the second side surface of the active pattern, the word line structure extending in the first horizontal direction,
wherein the word line structure includes:
vertical structures spaced apart from each other in a second horizontal direction that intersects the first horizontal direction, the vertical structures including word lines;
a support layer in contact with lower surfaces of the vertical structures;
capping patterns disposed at a level that is a same level as a level of the support layer; and
an air gap between the vertical structures,
wherein the support layer includes openings spaced apart from each other in the first horizontal direction, and
wherein at least a portion of each of the capping patterns is disposed in the openings.

14. The semiconductor device of claim 13, wherein the support layer and the capping patterns define a lower limit of the air gap.

15. The semiconductor device of claim 13, wherein:
the support layer includes an external surface in contact with the back gate structure and internal surfaces exposed by the openings, and
the capping patterns are in contact with the internal surfaces.

16. The semiconductor device of claim 15, wherein the support layer includes first portions, the external surface of which is concave, and second portions alternately disposed with the first portions in the first horizontal direction.

17. The semiconductor device of claim 16, wherein one of the first portions overlaps the active pattern in the second horizontal direction.

18. The semiconductor device of claim 15, wherein:
a length of each of the capping patterns in the vertical direction is less than a length of the support layer in the vertical direction, and
each of the internal surfaces of the support layer includes a portion exposed by the air gap.

19. The semiconductor device of claim 15, wherein:
in a longitudinal cross-sectional view, the internal surfaces of the support layer include a curved surface, and
a horizontal width of each of the capping patterns in the second horizontal direction increases as a distance from the contact structure increases.

20. A semiconductor device comprising:
an active pattern including a first side surface and a second side surface opposite to the first side surface, the active pattern extending in a vertical direction;
a bit line structure and contact patterns in contact with the active pattern, the bit line structure and the contact patterns spaced apart from each other in the vertical direction with the active pattern interposed therebetween;
an information storage structure connected to the contact patterns;
a back gate structure in contact with the first side surface of the active pattern, the back gate structure extending in a first horizontal direction and including a back gate electrode; and
a word line structure in contact with the second side surface of the active pattern, the word line structure extending in the first horizontal direction,
wherein the word line structure includes:
vertical structures spaced apart from each other in a second horizontal direction that intersects the first horizontal direction, the vertical structures including word lines;
gate dielectric layers in contact with the second side surface of the active pattern and the vertical structures;
a support layer overlapping the vertical structures in the vertical direction; and
an air gap between the vertical structures,
wherein the air gap exposes one of the bit line structure and the contact patterns, and
wherein a length of each of the vertical structures in the vertical direction is less than a length of each of the gate dielectric layers in the vertical direction.
